(19) United States
(12) Patent Application Publication
(10) Pub. No.: US 2015/0076612 A1
(43) Pub. Date: Mar. 19, 2015

(54) Semiconductor Device

(71) Applicant: Renesas Electronics Corporation, Kawasaki-shi, (JP)

(72) Inventor: Yukio MAKI, Kawasaki-shi (JP)

(21) Appl. No.: 14/462,376

(22) Filed: Aug. 18, 2014

(30) Foreign Application Priority Data
Sep. 17, 2013 (JP) 2013-191923

(51) Int. Cl. H01L 27/11; H01L 23/538

(52) U.S. Cl. CPC H01L 27/1104; H01L 23/5386
USPC 257/368

(57) ABSTRACT

The semiconductor device includes a bit line, a word line intersecting the bit line, a plurality of first contact patterns, and a plurality of second contact patterns. The word line extends so as to intersect the bit line in plan view. Each of the first contact patterns is elongated in the direction in which the bit line extends in plan view. Each of the second contact patterns is elongated in directions inclined with respect to the respective directions in which the bit line and the word line extend in plan view. The first contact patterns and the second contact patterns are formed in the same layer over the main surface of a semiconductor substrate.

### CROSS-REFERENCE TO RELATED APPLICATIONS

The disclosure of Japanese Patent Application No. 2013-191923 filed on Sep. 17, 2013 including the specification, drawings and abstract is incorporated herein by reference in its entirety.

### BACKGROUND

The present invention relates to a semiconductor device.

With high integration and miniaturization of semiconductor devices, there is an increasing tendency in which a plurality of fine elements, forming a semiconductor device, are multi-layered so as to be overlapped with each other in plan view. With semiconductor devices being multi-layered, a technique is often used, in which an active region and a gate electrode of a transistor formed over the surface of a semiconductor substrate, and a layer above the transistor are electrically coupled together by a conductive layer referred to as a contact plug.

An example of a semiconductor device having such a contact plug includes, for example, an SRAM (Static Random Access Memory) A so-called Advanced SRAM, collectively having the configurations and functions of an SRAM and a DRAM (Dynamic Random Access Memory) in order to further integrate the SRAM, is disclosed, for example, in Japanese Unexamined Patent Publication No. 2004-79696 (Patent Document 1)

### RELATED ART DOCUMENT

### Patent Document

[Patent Document 1] Japanese Unexamined Patent Publication No. 2004-79696

### SUMMARY

An Advanced SRAM includes: a contact pattern coupled to the gate electrode of a driver transistor via a plug; a contact pattern coupled to the source/drain region of an access transistor via a plug; and the like.

When the dimensions of fine elements that form a semiconductor device and the margin between respective patterns are reduced with the high integration of a semiconductor device, there is the possibility that the margin between the aforementioned contact patterns may be reduced and hence a short circuit may be caused by these contact patterns being in contact with each other. If a short circuit is caused between these contact patterns, the function as a semiconductor device may be impaired.

Other problems and new characteristics will become clear from the description and accompanying drawings of the present specification.

According to one embodiment, a semiconductor device includes a semiconductor substrate, a bit line, a word line, a plurality of first contact patterns, and a plurality of second contact patterns. The semiconductor substrate has a main surface, and the bit line extends over the main surface. The word line extends over the main surface so as to intersect the bit line in plan view. Each of the first contact patterns includes at least one of a contact pattern elongated in the direction in which the bit line extends and a contact pattern elongated in the direction in which the word line extends in plan view. Each of the second contact patterns is elongated in directions inclined with respect to the respective directions in which the bit line and the word line extend in plan view. The first contact patterns and the second contact patterns are formed in the same layer over the main surface.

In one embodiment, each of the second contact patterns is elongated in directions inclined with respect to the respective directions in which the bit line and the word line extend. Accordingly, the distance between each of the second contact patterns and the first contact pattern adjacent thereto can be made larger than the case where each of the second contact patterns is elongated in the direction in which the bit line or the word line extends. Accordingly, a short circuit between each of the second contact patterns and the first contact pattern adjacent thereto can be suppressed from occurring, and the function of a semiconductor device can be suppressed from being deteriorated.

### BRIEF DESCRIPTION OF THE DRAWINGS

FIG. 1 is a schematic plan view of a semiconductor device according to one embodiment;

FIG. 2 is an equivalent circuit diagram of a memory cell that forms a semiconductor device according to one embodiment;

FIG. 3 is a schematic sectional view for specifically explaining the equal circuit in FIG. 2;

FIG. 4 is a schematic plan view illustrating arrangements of an active region, a plug layer, a gate contact, and a gate electrode in a partial region of a memory cell region in FIG. 3 according to one embodiment;

FIG. 5 is a schematic plan view in which the respective components illustrated in FIG. 4 and bit lines, word lines, and contacts, which are located in the layers above the respective components, are overlapped with each other in the same region as that in FIG. 4 according to one embodiment;

FIG. 6 is a schematic sectional view illustrating modes of transistors that form a semiconductor device of one embodiment, and coupling layers and contact patterns of the transistors, in the area of FIG. 4 and the area taken along VI-VI Line in FIG. 5; and

FIG. 7 is a schematic plan view of a comparative example of FIG. 5.

### DETAILED DESCRIPTION

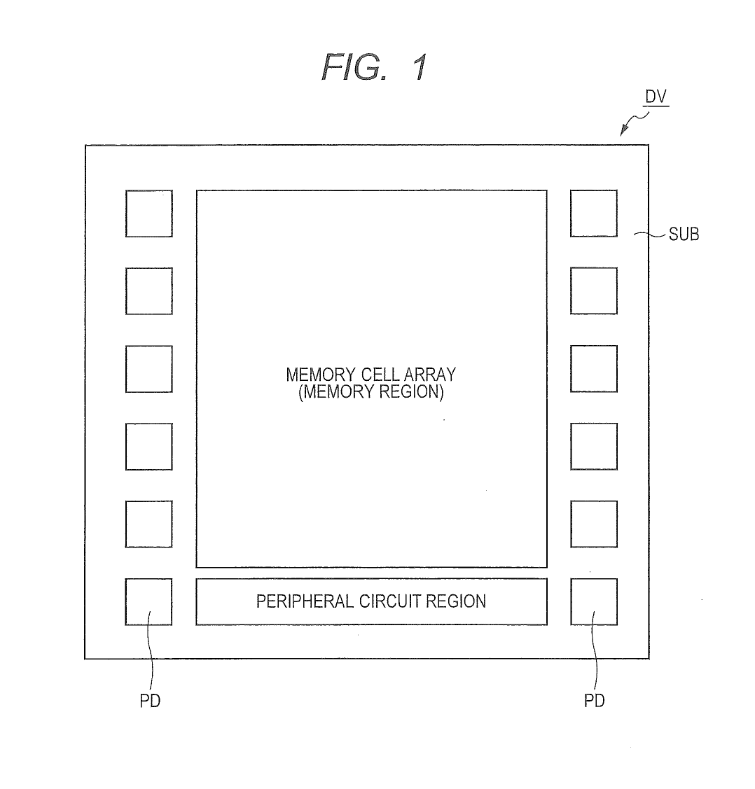

Hereinafter, embodiments will be described based on the accompanying drawings. With reference to FIG. 1, a semiconductor device DV of one embodiment is a semiconductor chip in which a plurality of types of circuits are formed over a main surface of a semiconductor substrate SUB such as a semiconductor wafer including, for example, silicon single crystal. As an example, the circuits that form the semiconductor device DV include a memory cell array (memory region), a peripheral circuit region, and a pad region PD.

The memory cell array is a main memory region of the semiconductor device DV and includes an SRAM. The peripheral circuit region and the pad region PD are formed outside the memory cell array in plan view. A plurality of the pad regions PD are formed, for example, outside the memory cell array so as to be spaced apart from each other.

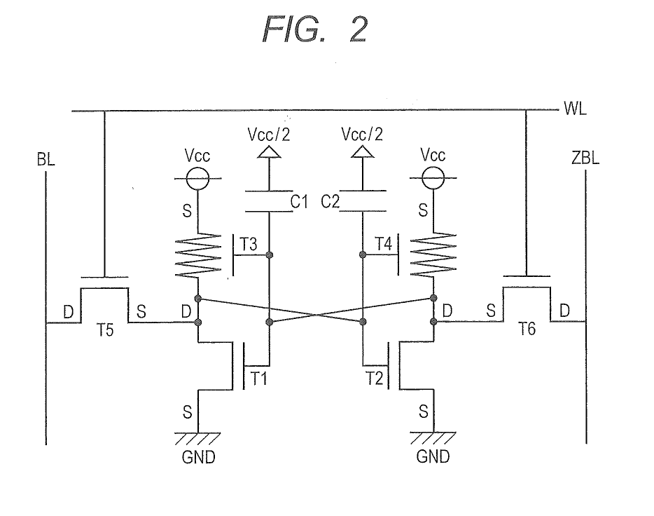

Subsequently, the configuration of a semiconductor device of the present embodiment will be described by using the memory cell in FIG. 2 as an example.

With reference to FIG. 2, a semiconductor device of the present embodiment includes, in a memory region, an SRAM (static type memory cell) having a pair of bit lines BL and ZBL, a word line WL, a flip-flop circuit, and a pair of access transistors T5 and T6.

The flip-flop circuit has driver transistors T1 and T2 and load transistors T3 and T4. The driver transistor T1 and the load transistor T3 form one CMOS (Complementary Metal Oxide Semiconductor) inverter, and the driver transistor T2 and the load transistor T4 form the other CMOS inverter. The flip-flop circuit includes these two CMOS inverters. An SRAM is a semiconductor memory device in which processing for returning a charge that is stored as information to an original state at a predetermined cycle, which is referred to as so-called refresh, is not required by having a flip-flop circuit. The SRAM in the present embodiment further has capacitors C1 and C2 as a DRAM (Dynamic Random Access Memory).

The driver transistors T1 and T2 that form the flip-flop circuit are, for example, n-channel type MOS transistors. The load transistors T3 and T4 are, for example, p-channel type TFTs (Thin Film Transistors). The access transistors T5 and T6 are, for example, n-channel type MOS transistors. Thus, the SRAM of the present embodiment is a so-called Advanced SRAM in which the load transistors are TFTs and capacitors as a DRAM are added.

In the flip-flop circuit, the gate electrodes of the driver transistor T1 and the load transistor T3, and one electrode of the capacitor C1 are electrically coupled together, and they are electrically coupled to the source electrode S of the access transistor T6. The source electrode S of the access transistor T6 is electrically coupled to the drain electrodes D of the driver transistor T2 and the load transistor T4, and the region where they are coupled together functions as a first storage node portion.

The gate electrodes of the driver transistor T2 and the load transistor T4 and one electrode of the capacitor C2 are electrically coupled together, and they are electrically coupled to the source electrode S of the access transistor T5. The source electrode S of the access transistor T5 is electrically coupled to the drain electrodes D of the driver transistor T1 and the load transistor T3, and the region where they are coupled together functions as a second storage node portion.

The source electrodes S of the driver transistors T1 and T2 are electrically coupled to GND potentials, and the source electrodes S of the load transistors T3 and T4 are electrically coupled to Vcc interconnections (power supply interconnections) for applying a voltage Vcc. Further, the other electrodes of the capacitors C1 and C2 are electrically coupled to Vcc/2 interconnections for applying a voltage Vcc/2, which is ½ of the aforementioned voltage Vcc. The bit line pair BL and ZBL are respectively coupled to the drain electrodes D of the pair of the access transistors T5 and T6.

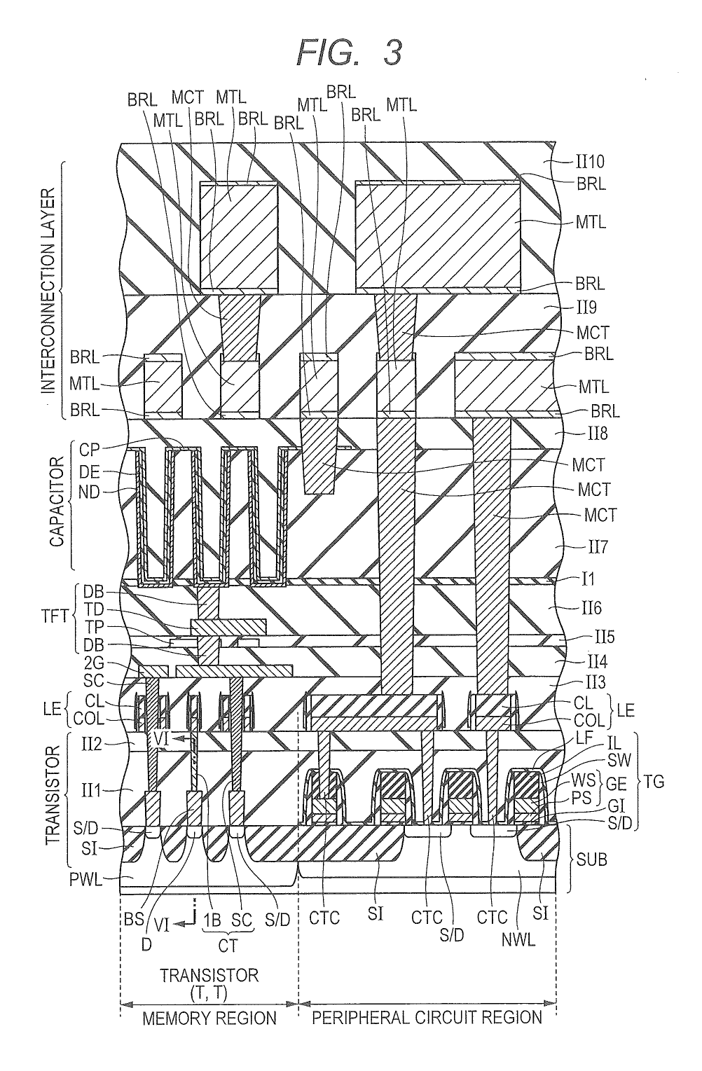

Subsequently, the more specific configuration of the semiconductor device illustrated in FIG. 2 will be described by using the schematic sectional view of FIG. 3. However, the sectional view of FIG. 3 does not illustrate the sectional mode of a specific region, but illustrates respective elements such as the transistors and capacitors illustrated in FIG. 2, which are collected for illustrating the shapes thereof in the semiconductor device.

With reference to FIG. 3, a semiconductor device of one embodiment is formed over one main surface of the semiconductor substrate SUB including, for example, silicon.

A memory region and a peripheral circuit region are formed over the main surface of the semiconductor substrate SUB. The memory region is a region where the SRAM (in particular, Advanced SRAM) in FIG. 1 is formed, and the peripheral circuit region is a peripheral region of the region where the SRAM in FIG. 1 is formed, that is, a region where, for example, a signal input/output circuit is formed.

The memory region has an isolation region and an active region. An STI (Shallow Trench Isolation) as the isolation region is formed over part of the surface of the semiconductor substrate SUB in the memory region. This STI is formed by embedding an insulating layer SI in a trench formed in the surface of the semiconductor substrate SUB.

A region other than the isolation region of the memory region, that is, a region where the STI is not formed is a so-called active region. The active region is formed over the surface of the semiconductor substrate SUB so as to be enclosed by the isolation region. One active region of the memory region and another active region adjacent to the one active region are electrically isolated from each other by the isolation region sandwiched between the two active regions.

A p-type well region PWL, into which, for example, p-type conductive impurities have been injected, is formed in the semiconductor substrate SUB in the memory region.

A plurality of (n-type) MOS transistors, each having a pair of source/drain regions S/D, are formed over the surface of the semiconductor substrate SUB in each active region. For example, the region S/D on the left side and the right side of the memory region in FIG. 3 are regions where the source region S of the access transistor (corresponding to the source electrode S in FIG. 2) and the drain region D of the driver transistor (corresponding to the drain electrode D in FIG. 2) are planarly overlapped with each other, and the access transistor and the driver transistor share the region S/D. These regions S/D are formed in the active region in FIG. 3. The region D formed in the active region at the center of FIG. 3 is the drain region D of the access transistor T5 (T6), and is coupled to the bit line BL (or ZBL).

An interlayer insulating film II1 including, for example, a silicon oxide film is formed to cover the main surface of the semiconductor substrate SUB over which the aforementioned MOS transistors, etc., are formed. A plurality of plug layers BS, for electrically coupling the source region S and/or the drain region D to a layer above these regions, are formed to be spaced apart from each other. The plug layer BS is formed by polycrystalline silicon to which, for example, conductive impurities have been added, the polycrystalline silicon filling an opening formed in a partial region of the interlayer insulating film II1. The plug layer BS is formed to reach, for example, a pair of the source/drain regions S/D over the main surface of the semiconductor substrate SUB, and to extend, in a relatively lower region of the interlayer insulating film II1, in the direction perpendicular to the main surface (vertical direction in FIG. 3).

An interlayer insulating film II2 including, for example, a silicon oxide film is formed over the interlayer insulating film II1. An interlayer insulating film II3 including, for example, a silicon oxide film is formed to be in contact with the upper surface of the interlayer insulating film II2. Further, interlayer insulating films II4, II5, and II6, each including, for example, a silicon oxide film, are sequentially formed thereover. Furthermore, an interlayer insulating film I1 including, for example, a silicon nitride film is formed to be in contact with the upper surface of the interlayer insulating film II6. Still furthermore, interlayer insulating films II7, II8, II9, and II10, each including, for example, a silicon oxide film, are sequentially formed to be in contact with the upper surface of the interlayer insulating film I1.

A plurality of (e.g., five) interconnections COL are formed over the interlayer insulating film II2 (so as to be in contact with the upper surface of the film II2), so as to be spaced apart from each other. The interconnection COL extends in the depth direction of the sheet of FIG. 3. A covering insulating film CL is formed to cover the upper surface and the side surface of the interconnection COL, so that an interconnection structure CL, including the interconnection COL and the covering insulating film CL (including a sidewall insulating film SW), is formed.

Interconnections that function as the bit line pair BL and ZBL and those that function as a ground line GND coexist in the interconnections COL. The interconnections COL that function as the bit line pair BL and ZBL are electrically coupled to each of the drain regions D of the access transistors T5 and T6 located, for example, at the center of the memory region in FIG. 3. The interconnections COL that function as the ground line GND are electrically coupled to each of the source regions S, for example, of the driver transistors T1 and T2.

The interlayer insulating film II3 is formed to cover the interlayer insulating film II2 and the interconnection structure LE, and a lower layer interconnection 2G is formed over the interlayer insulating film II3. The lower layer interconnection 2G corresponds to the first and second storage node portions in FIG. 2.

A bit line contact 1B coupling the plug layer BS and the interconnection COL and a storage node contact SC coupling the plug layer BS and the lower layer interconnection 2G are formed in the memory region. Herein, these are collectively referred to as a contact pattern CT.

The contact pattern CT is formed by polycrystalline silicon to which, for example, conductive impurities have been added or tungsten, etc., the polycrystalline silicon or tungsten, etc., filling an opening formed in a partial region of the interlayer insulating film II1, similarly to the plug layer BS. The contact pattern CT is formed to reach, for example, the plug layer BS and to extend, in a relatively upper region of the interlayer insulating film II1, in the direction perpendicular to the main surface.

In more detail, the bit line contact 1B extends in the direction perpendicular to the main surface so as to reach the plug layer BS, located directly below, after penetrating, from the bit line BL, the interlayer insulating films II2 and II1. The storage node contact SC extends in the direction perpendicular to the main surface so as to reach the plug layer BS, located directly below, after penetrating, from the lower layer interconnection 2G, the interlayer insulating films II3 and II2 and part of the interlayer insulating film II1. The storage node contact SC penetrates a region between a pair of the interconnection structures LE, which are adjacent to each other in FIG. 3.

The lower layer interconnection 2G is arranged such that a capacitor formed in an upper layer and a transistor formed in a lower layer are electrically coupled together by, for example, the storage node contact SC. It is preferable to form the lower layer interconnection 2G in a region generally overlapped with the capacitor in plan view. It is preferable to form the lower layer interconnection 2G by a polycrystalline silicon film having, for example, impurity ions. When the transistor to be formed in a lower layer is, for example, an n-channel type transistor, the lower layer interconnection 2G may be formed by polycrystalline silicon including, for example, n-type impurity ions, in order to facilitate the electrical coupling with the transistor TG.

A polycrystalline silicon layer TP is formed over the interlayer insulating film II4. The polycrystalline silicon layer TP is a semiconductor layer including polycrystalline silicon into which impurity ions have been introduced, and has both the channel region of a TFT as the load transistors T3 and T4 in the SRAM (see FIG. 2) and a pair of source/drain regions that sandwich the channel region. Also, the polycrystalline silicon layer TP includes part of a power supply interconnection for supplying power to the TFT. It is preferable to form the polycrystalline silicon layer TP in a region generally overlapped with the capacitor in plan view.

The gate electrode layer TD of the TFT is formed over the interlayer insulating film II5. It is preferable that the gate electrode layer TD is a semiconductor layer including polycrystalline silicon having impurity ions.

It is preferable that the gate electrode layer TD and the lower layer interconnection 2G are electrically coupled together by a conductive layer referred to as a data node contact DB. This data node contact DB is electrically coupled to the polycrystalline silicon layer TP by being in contact with an end portion of the polycrystalline silicon layer TP in the middle of the extension from the gate electrode layer TD toward the lower layer interconnection 2G. The data node contact DB is a conductive layer for forming the flip-flop circuit (cross couple) of the SRAM, and is formed by a semiconductor layer including polycrystalline silicon having impurity ions, similarly, for example, to the gate electrode layer TD. It is preferable to form the data node contact DB so as to penetrate the interlayer insulating films from the gate electrode layer TD to the lower layer interconnection 2G, and so as to extend in the direction perpendicular to the surface of the semiconductor substrate SUB.

The data node contact DB may be formed to electrically couple a layer upper than or equal to the gate electrode layer TD, for example, the gate electrode layer TD to the capacitor, or formed to electrically couple a layer lower than or equal to the lower layer interconnection 2G, for example, the lower layer interconnection 2G to the plug layer BS. In this case, the data node contact DB may be formed to reach the plug layer BS after penetrating, for example, from the capacitor, the gate electrode layer TD, the polycrystalline silicon layer TP, and the lower layer interconnection 2G.

The capacitor is formed over the interlayer insulating film II6. The capacitor is electrically coupled to the data node contact DB by being in contact with the upper surface thereof. The capacitor has a lower electrode. ND, a dielectric layer DE, and an upper electrode CP. The lower electrode ND is coupled to the data node contact DB. The upper electrode CP faces the lower electrode ND with the dielectric layer DE being interposed therebetween.

A metal interconnection MTL is formed over layers above the capacitor, for example, over the interlayer insulating film II8 and the interlayer insulating film II9. It is preferable that the metal interconnection MTL includes, for example, aluminum, an alloy of aluminum and copper, copper, tungsten, or the like, and the upper surface and the lower surface thereof are covered with barrier metal BRL including, for example, tantalum, titanium, titanium nitride, or the like. Also, it is preferable that the coupling between the above metal interconnections MTL and that between the metal interconnection MTL and the bit line BL are made by a metal contact conductive layer MCT including, for example, copper, tungsten, or the like.

On the other hand, an n-type well region NWL, into which, for example, n-type conductive impurities have been injected, is formed in the peripheral circuit region, but instead the p-type well region PWL may be formed. An isolation region and an active region are also formed in the peripheral circuit region, similarly to the memory region. The isolation region is formed by the STI, similarly to the memory region. A plurality of (p-type) MOS transistors TG are formed over the surface of the semiconductor substrate SUB in the active region. The transistor TG has a pair of source/drain regions S/D, a gate insulating film GI, a gate electrode GE, and an insulating layer IL. Each of the pair of source/drain regions S/D is formed over the surface of the semiconductor substrate SUB so as to be spaced apart from each other. The gate insulating film GI is formed over the surface of the semiconductor substrate SUB in an area sandwiched by the pair of source/drain regions S/D. The gate electrode GE and the insulating layer IL are formed over the gate insulating film GI, and have a laminated structure in which the gate electrode GE and the insulating layer IL are laminated in this order.

The gate electrode GE has a so-called polycide structure in which, for example, a polycrystalline silicon layer PS and a tungsten silicide layer WS are laminated in this order, and the gate electrode GE is formed in the same layer and has the same configuration as each of the gate electrodes GE1 and GE2 in the later-described memory region. The insulating layer IL includes, for example, a silicon oxide film and/or a silicon nitride film, and the gate electrode GE is etched by using the insulating layer IL as a mask. The sidewall insulating film SW is formed over sidewalls of this gate electrode GE and the insulating layer IL. It is preferable that the sidewall insulating film SW includes, for example, a silicon nitride film, but the film SW may include a combination of a silicon oxide film and a silicon nitride film. The insulating layer IL and the sidewall insulating film SW serve as a stopper film for the etching executed when a self-aligning technique is performed, in a region of the memory cell, in particular, a region where an opening for forming the plug layer BS is formed.

In FIG. 3, the insulating layer IL is formed over the gate electrode GE, and the gate electrode GE is electrically coupled to the another interconnection in a region extending in the depth direction of the sheet not illustrated in the sectional view of FIG. 3. Although detailed description is omitted, each transistor TG in the peripheral circuit region is electrically coupled to the metal interconnection MTL through a contact conductive layer CTC, a conductive layer as the same layer as the bit line BL, and the metal contact conductive layer MCT, etc.

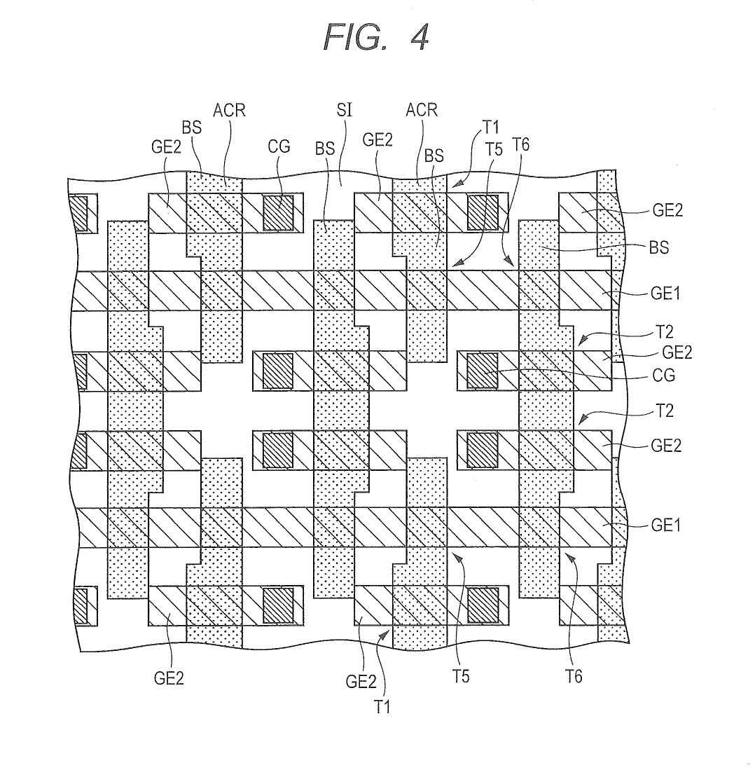

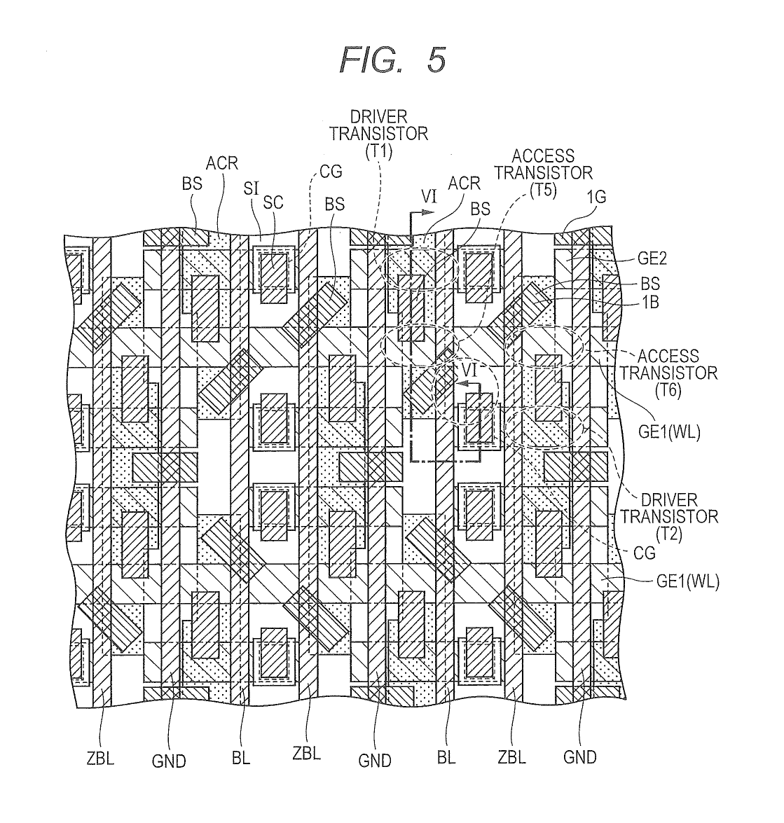

Subsequently, the planar mode of the semiconductor device illustrated in FIG. 3, in particular, of the memory region will be described in more detail with reference to FIGS. 4 and 5. FIGS. 4 and 5 illustrate the mode of a mask for forming the memory region, so that a region to be formed as, for example, a circular shape in an actual product may be illustrated as a rectangular pattern in FIGS. 4 and 5.

With reference to FIG. 4, this view only illustrates the arrangement of each component in the plug layer, a gate contact, the gate electrode, and layers below them (located near to the semiconductor substrate SUB), when a partial region of the memory region of the semiconductor device in FIG. 3 is planarly viewed. With reference to FIG. 5, this view illustrates the arrangements of each component illustrated in FIG. 4 and each component in the layers above them (opposite to the semiconductor substrate SUB), when the same region as that in FIG. 4 is planarly viewed. Even in FIG. 5, however, the structures in the layers above the bit line BL in FIG. 3 are not illustrated.

Mainly with reference to FIG. 4, a plurality of active regions ACR are formed over the main surface of the semiconductor substrate SUB in the memory region so as to be spaced apart from each other. Although the planar shape of the active region ACR is arbitrary, it is preferable to determine the planar shape thereof in consideration of the arrangement of an element such as the driver transistor and the arrangement of the plug layer BS as a coupling layer for electrically coupling to the element. In FIG. 4, for example, each of the active regions ACR basically has a shape close to a rectangular shape in which the active region ACR extends long in the vertical direction in the view and has a constant width in the horizontal direction, but has, in the central portion with respect to the vertical direction, a projecting portion whose width in the horizontal direction is slightly larger than that in an end portion with respect to the vertical direction. Two projecting portions of a pair of the active regions ACR, which are adjacent to each other with respect to the horizontal direction in the view, are oriented in the directions opposite to each other (right side or left side). Also, the projecting portion faces a region by which the active regions ACR, roughly adjacent to each other with respect to the horizontal direction in the view, are divided (i.e., the isolation region where the insulating layer SI is formed).

A plurality of the gate electrodes GE1 are the gate electrodes of the access transistors T5 and T6 in FIG. 2, each of which extends in a straight line over the main surface of the semiconductor substrate SUB in the memory region, without being basically interrupted with respect to the horizontal direction in FIG. 4. In FIG. 4, two gate electrodes GE1 are arranged to be spaced apart from each other by a constant space with respect to a direction intersecting the direction in which they extend (i.e., the vertical direction in the view) in plan view.

A plurality of the gate electrode GE2 are the gate electrodes of the driver transistors T1 and T2 in FIG. 2, each of which extends in the horizontal direction in the view so as to be roughly parallel to the gate electrode GE1, over the main surface of the semiconductor substrate SUB in the memory region. These gate electrodes GE2 are divided so as to have a constant length with respect to the horizontal direction in the view, and are arranged to be spaced apart from each other by a constant space with respect to the vertical direction in the view intersecting the direction in which they extend. The space between a pair of the gate electrodes GE1, adjacent to each other with respect to the vertical direction in the view, and that between one gate electrode. GE2 and the gate electrode GE1 adjacent thereto with respect to the vertical direction in the view are almost equal to each other.

Although these driver transistors T1 and T2 and access transistors T5 and T6 are not illustrated in FIG. 3, they correspond to the MOS transistors each including the source/drain region S/D formed in the active region in FIG. 3.

The plug layer BS is formed in a region of the active region ACR, the region excluding the gate electrode GE1 of each access transistor and the gate electrode GE2 of each driver transistor. That is, the plug layer BS is formed in the active region ACR so as to fill a region sandwiched by the gate electrodes GE1 and GE2, etc.

In other words, the plug layer BS is formed to be coupled to the source/drain region of each of the driver transistor and the access transistor. Accordingly, the plug layer BS is overlapped with the source/drain region in plan view.

The gate contact CG is formed in the isolation region where the insulating layer SI is formed over the main surface of the semiconductor substrate SUB, the isolation region excluding the active region ACR, so as to planarly overlap the gate electrode GE2 of the driver transistor.

With reference to FIG. 5, a plurality of word lines WL, each extending in the horizontal direction in the view when planarly viewed, extend over the main surface of the semiconductor substrate SUB so as to be spaced apart from each other. The word lines WL exist, for example, as the gate electrodes GE1 (the same as the gate electrodes GE1) that form the access transistors T5 and T6. A plurality of interconnections BL, ZBL, and GND, each intersecting the word lines (e.g., at right angles) in plan view, i.e., each extending in the vertical direction in the view, extend so as to be spaced apart from each other (extend in parallel with each other) over the main surface of the semiconductor substrate SUB.

In FIG. 5, a pair of the bit lines BL and ZBL extend so as to be spaced apart from and in parallel with each other, and the ground line GND extends in a place, the place being far from the bit line ZBL by the space between the adjacent bit lines BL and ZBL and in the direction opposite to the direction in which these bit lines BL and ZBL are arranged, and extends in a direction almost the same direction as those of the bit lines BL and ZBL (e.g., in the parallel direction). In other words, the bit lines BL (ZBL) and the ground lines GND extend in almost parallel with each other such that a cycle of the bit line BL, the bit line ZBL, and the ground line GND is repeated in this order with respect to the horizontal direction in FIG. 5.

In FIG. 5, the upper region and the lower region, which are divided by a non-illustrated straight line extending in the horizontal direction and through the central portion with respect to the vertical direction, are basically symmetric with respect to the line. A region enclosed by a rectangular shape is made as a unit cell, in which the distance between the word lines WL adjacent to each other with respect to the vertical direction in FIG. 5 is set to be three times larger than the distance between the bit line BL (ZBL) and the ground line GND adjacent to each other with respect to the horizontal direction in the view; and the pattern of the respective components in the unit cell is basically and planarly repeated.

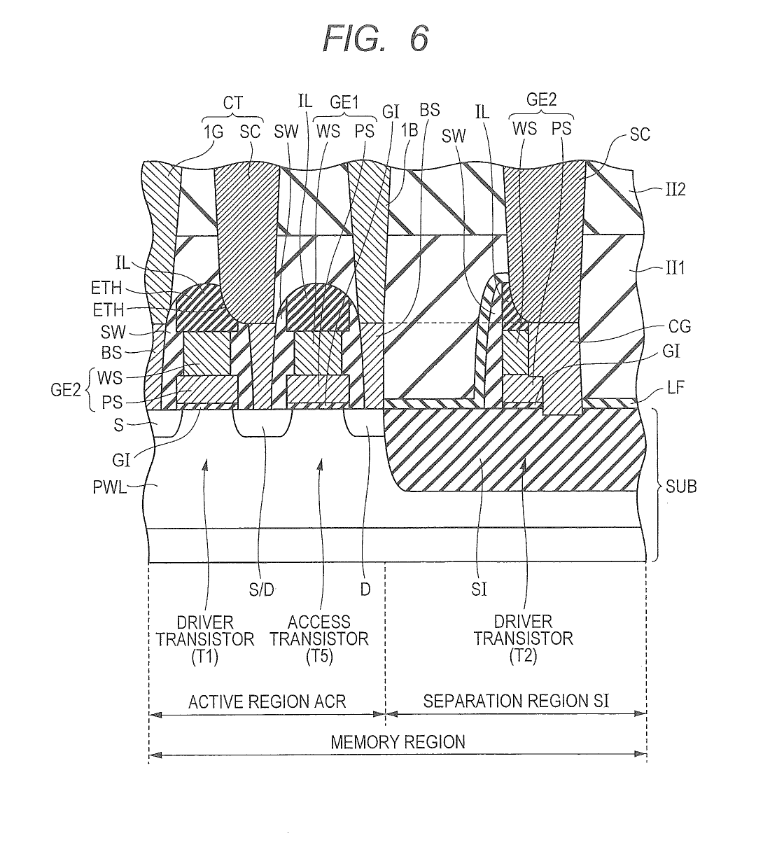

With reference to FIG. 5 and FIG. 6 that is a schematic sectional view of the region taken along the bending VI-VI Line illustrated in FIG. 5, the driver transistor T1 (see FIG. 2), the access transistor T5 (see FIG. 2), and the gate electrode GE2 of the driver transistor T2 (see FIG. 2) are lined up in this order from the left side of FIG. 6. The left half of FIG. 6 belongs to the active region ACR, and the right half belongs to the isolation region SI. FIG. 6 is also a schematic sectional view of the area taken along VI-VI Line in FIG. 3.

As illustrated in FIG. 6, the driver transistor has a pair of the source/drain regions S/D, the gate insulating film GI, the gate electrode GE2, the insulating layer IL, and the sidewall insulating film SW. The gate electrode GE2 has a configuration in which the polycrystalline silicon layer PS and the tungsten silicide layer WS are laminated in this order. Similarly, the access transistor also has a pair of the source/drain regions S/D, the gate insulating film GI, the gate electrode GE1, the insulating layer IL, and the sidewall insulating film SW. The gate electrode GE1 has a configuration in which the polycrystalline silicon layer PS and the tungsten silicide layer WS are laminated in this order. Each of the gate electrodes GE1 and GE2 in the memory region is formed in the same layer and has the same configuration as the gate electrode GE in the peripheral circuit region.

A pair of the source/drain regions S/D of the driver transistor and the access transistor are formed over the semiconductor substrate SUB (p-type well region PWL) in the active region ACR. The drain region of the driver transistor on the left side of FIG. 6 and the source region of the access transistor include a common impurity region, which corresponds, for example, to the intersection between the drain region D of the driver transistor T1 and the source region S of the access transistor T5 in FIG. 2. Accordingly, it can be considered that the driver transistor on the left side of FIG. 6 corresponds, for example, to the driver transistor T1 in FIG. 2 and the access transistor in FIG. 6 corresponds, for example, to the access transistor T5 in FIG. 2.

It can be considered that, in the driver transistor on the right side of FIG. 6, the gate electrode GE2 is located over the isolation region SI over at least VI-VI Line and the driver transistor corresponds to the driver transistor T2 (see FIG. 2) different from the driver transistor T1 on the left side.

With reference to FIGS. 2, 5, and 6, the plug layer BS (first coupling layer), for electrically coupling the source region S (main surface of the semiconductor substrate SUB) and the upper layer, is formed over the source region S of the driver transistor T1. The ground contact 1G (first contact pattern) is formed to be in contact with the upper surface of the plug layer BS. The ground contact 1G is coupled to the GND potential (i.e., ground line GND in FIG. 5) to which the source region S of the driver transistor T1 in FIG. 2 is coupled.

Subsequently, over the region where the drain region D of the driver transistor T1 and the source region S of the access transistor T5 are overlapped with each other, the plug layer BS (first coupling layer) for electrically coupling the region and the upper layer is formed. The storage node contact SC (first contact pattern) is formed to contact the upper surface of the plug layer BS.

Over the drain region D of the access transistor T5, the plug layer BS (second coupling layer) for electrically coupling the drain region D (main surface of the semiconductor substrate SUB) and the upper layer is formed. The bit line contact 1B (second contact pattern) is formed to be in contact with the upper surface of the plug layer BS. The bit line contact 1B is coupled to the bit line BL to which the drain region D of the access transistor T5 in FIG. 2 is coupled.

The gate electrode GE2 of the driver transistor T2 is coupled to the gate contact CG (first coupling layer) over the isolation region SI. The gate contact CG is a conductive layer formed by being isolated from the same layer as the plug layer BS in the active region, and is used as a contact for taking out the gate electrode GE2 to another region by being formed to superimpose the gate electrode GE2 in the isolation region. Accordingly, the gate contact CG is formed to be in contact with the gate electrode GE2. However, an opening for forming the gate contact CG is normally formed by a usual photoengraving technique and etching, not by a self-aligning technique. As a result, the opening is often formed to more or less shift from the position of the gate electrode GE2. In FIG. 6, the gate contact CG is formed to overlap the right roughly-half region of the gate electrode GE2 (to slightly shift from the gate electrode GE2 in plan view).

The storage node contact SC (first contact pattern) is formed to be in contact with the upper surface of the gate contact CG. The storage node contact SC over the plug layer BS of the driver transistor T1 and the storage node contact SC over the gate contact CG of the driver transistor T2 are coupled to the same lower interconnection 2G and the data node contact DB (see FIG. 3) in a layer above the region illustrated in FIG. 6, to form the flip-flop circuit (cross couple) of the SRAM. Thus, the portion, in which a plurality of the storage node contacts SC are electrically coupled together by the same lower layer interconnection 2G and the data node contact DB, corresponds to the aforementioned second storage node portion where a portion, in which the drain region D of the driver transistor T1 and the source region S of the access transistor T6 are coupled together in FIG. 2, and the gate electrode of the driver transistor T2 are coupled together.

A liner film LF including, for example, a silicon nitride film may be formed over the surface of the isolation region SI, and the liner film LF may be formed to cover the gate electrode GE2.

As described above, the coupling layer coupled to the main surface of the semiconductor substrate SUB is basically the plug layer BS in the active region, and that coupled to the main surface of the semiconductor substrate SUB is the gate contact CG in the gate electrode located in a region that is not the active region.

With reference to FIGS. 5 and 6 again, a plurality of the plug layers BS and the gate contacts CG are formed over the main surface of the semiconductor substrate SUB. Also, both a plurality of the first contact patterns 1G and SC and a plurality of the second contact patterns 1B are present. Accordingly, each of the contact patterns 1G and SC is formed to be in contact with the upper surface of each of the plug layers BS or the gate contacts CG, and each of the second contact patterns 1B is formed to be in contact with the upper surface of each of the plug layers BS.

The plug layers BS and the gate contacts CG are formed to be in the same layer but isolated from each other. In addition, each of the first contact patterns 1G and SC and each of the second contact patterns 1B are formed to be isolated from the same layer over the main surface of the semiconductor device SUB.

With reference to FIG. 5 again, the first contact pattern means a contact pattern elongated in the direction in which the bit line BL extends (vertical direction in the view) or the direction in which the word line WL extends (horizontal direction in the view) in plan view; and the first contact pattern means a concept including both the ground contact 1G and the storage node contact SC. The second contact pattern means a contact pattern elongated in directions inclined with respect to the respective directions in which the bit line BL and the word line WL extend in plan view, and herein the second contact pattern specifically means the bit line contact 1B. Herein, for example, the expression of “the contact pattern is elongated in the direction in which the bit line BL extends” means that the long dimension of the contact pattern is oriented along the direction in which the bit line BL extends.

More specifically, each of the ground contact 1G, the storage node contact SC, and the bit line contact 1B has a planar shape elongated in one direction in FIG. 5. The ground contact 1G is the first contact pattern elongated in the horizontal direction in FIG. 5, i.e., in the direction in which the word line WL extends. The storage node contact SC is the first contact pattern elongated in the vertical direction in FIG. 5, i.e., in the direction in which the bit line BL extends. The bit line contact 1B is the second contact pattern elongated in inclined directions in FIG. 5, i.e., in directions inclined with respect to both the bit line BL and the word line WL.

The ground contact 1G is arranged such that the direction in which it extends is oriented along the direction in which the word line WL extends (horizontal direction in FIG. 5) and it partially overlaps one of the ground lines GND.

The storage node contact SC is arranged such that the direction in which it extends is oriented along the direction in which the bit line BL extends (vertical direction in FIG. 5) and it is sandwiched between a pair of the bit lines BL adjacent to each other. That is, it is preferable that the storage node contact SC is arranged not to overlap the bit line BL (ZBL) and the ground line GND. Thereby, the possibility that a short circuit may be caused between the storage node contact SC and the bit line BL is reduced.

The bit line contact 1B is arranged such that the direction in which it extends is inclined with respect to the respective directions in which the bit line BL and the word line WL extend and it partially overlaps one of the bit lines BL.

When each of the plug layer BS and the gate contact CG, including them directly below the bit line contact 1B arranged to be inclined, has, for example, a rectangular shape, the edge portion of it is formed to be oriented along the direction in which the bit line BL and the word line WL extend. That is, for example, the bit line contact 1B extends in directions inclined with respect to the respective directions in which the bit line BL and the word line WL extend in plan view; however, the plug layer BS directly below the bit line contact 1B is formed to be oriented along the directions in which the bit line BL and the word line WL extend, without extending in inclined directions.

Subsequently, the dimension and inclined angle of the bit line contact 1B arranged to be inclined will be described.

In FIG. 5, each of the ground contact 1G, the storage node contact SC, and the bit line contact 1B (which correspond to the first and second contact patterns) has a rectangular shape elongated in one direction in plan view. However, for example, these contact patterns 1G, SC, and 1B may have an arbitrary planar shape having in plan view, a large dimension in one direction and a small dimension (short dimension) smaller than the large dimension (long dimension) in a direction intersecting the one direction; and they may have, for example, an elliptical planar shape.

As illustrated in FIG. 6, these contact patterns CT (ground contact 1G, storage node contact SC, and bit line contact 1B) are formed by filling holes, usually formed by so-called dry etching, with a conductive material. Accordingly, they have a shape whose dimension in plan view, becomes smaller as advancing toward a deeper portion (toward a lower layer) (in other words, a shape whose section has a taper toward the depth direction). The plan view of FIG. 5 illustrates the planar shape and dimension at a constant depth with respect to the depth direction (e.g., the same depth as the uppermost surface of the plug layer BS).

Herein, it is preferable that the ratio of the planarly short dimension to the long dimension of these contact patterns 1G, SC, and 1B is (1):(1.23 or more). For example, when a contact pattern CT having a dimension (diameter) of 100 nm in a direction in plan view, is managed such that a dimension error is within ±10%, the maximum of the dimension (diameter) becomes 110 nm and the minimum 90 nm. When the dimension (diameter) of a contact pattern CT in one direction is, for example, the maximum of 110 nm and the dimension (diameter) thereof in the other direction is 90 nm, the contact pattern CT can be defined as an elongated planar shape when the ratio of the long dimension (diameter) to the short dimension (diameter) is 110/90=1.22 or more.

In addition, it is preferable that the inclined angle (α) of the bit line contact 1B, at which the bit line contact 1B is inclined in plan view, with respect to the direction in which the bit line BL or the word line WL extends, is 10°≦α≦80°, and particularly preferable that α is 30°≦α≦60°. By inclined at an angle of, for example, 10° or more, a short circuit can be suppressed even if a short margin larger than or equal to the dimensional error of the bit line contact 1B in plan view, is present. As an example, the direction of the long dimension of the bit line contact 1B in FIG. 5 is inclined at approximately 45° with respect to the directions in which the bit line BL and the word line WL respectively extend. Since the upper region and the lower region of FIG. 5, which are divided by a straight line extending in the horizontal direction and through the central portion with respect to vertical direction, are symmetric with respect to the line, the bit line contact 1B in the upper half of FIG. 5 extends such that the right side thereof is raised, while the bit line contact 1B in the lower half extends such that the right side thereof is lowered.

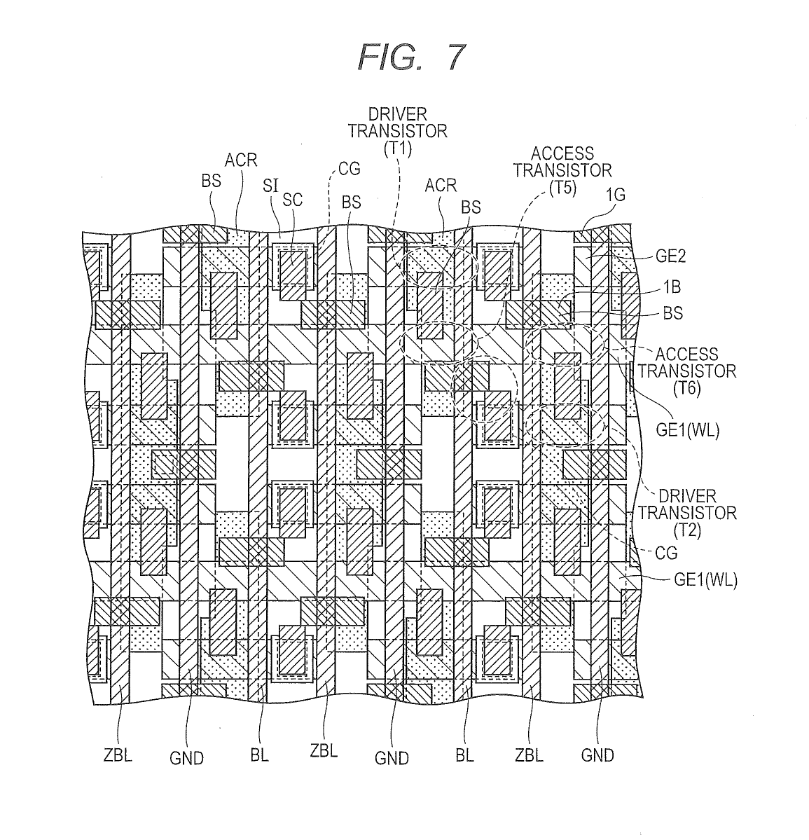

Subsequently, operations and effects of the present embodiment will be described with reference to a comparative example of FIG. 7. With reference to FIG. 7, this comparative example has a configuration similar to that of FIG. 5, but is different therefrom in the configuration of the bit line contact 1B. Specifically, the bit line contact 1B is formed such that the long dimension thereof is oriented along the direction in which the word line WL extends, similarly to the ground contact 1G.

The configurations of the present embodiment other than this are almost the same as that of Embodiment shown in FIG. 5, and hence like elements are denoted by like reference numerals and description of the elements is not repeated.

In the case of the comparative example of FIG. 7, when the miniaturization of an SRAM progresses and the margin between respective components in a semiconductor device continues to be reduced, there is the possibility that the bit line contact 1B and the storage node contact SC adjacent thereto (over the gate contact CG in the isolation region SI) may be in contact with each other, in particular, as in the portion illustrated by the circular dotted line in FIG. 7, which may cause a short circuit between them. Since the bit line contact 1B and the storage node contact SC are formed in the same layer over the semiconductor substrate SUB, their heights from the main surface of the semiconductor substrate SUB are almost equal to each other. Accordingly, there is the possibility that a short circuit may be caused relatively easily if they are close to each other in plan view.

Accordingly, in one embodiment, the bit line contact 1B is arranged such that the direction in which it extends is inclined with respect to the directions in which the word line WL and the bit line BL extend, as illustrated in FIGS. 4 and 5. With such a configuration, the insulating films (interlayer insulating films II1, II2) illustrated in FIG. 6 are interposed between the bit line contact 1B and the storage node contact SC adjacent thereto. Accordingly, a state can be secured even when the miniaturization of an SRAM progresses and the margin between respective component in a semiconductor device is reduced, in which the bit line contact 1B and the storage node contact SC, which are formed in the same layer, are not in contact with each other, and are electrically insulated from each other.

The bit line contact 1B has an elongated planar shape having a long dimension, so that it surely crosses the bit line BL, and a configuration can be formed, in which the bit line contact 1B planarly overlaps the bit line BL, thereby allowing a configuration to be formed, in which the bit line contact 1B and the bit line BL can be electrically coupled together.

Among a plurality of the contact patterns that form the configuration in FIG. 5, however, there are some contact patterns such as the ground pattern 1G in the view, which have, on the contrary, the possibility that a short circuit with another contact pattern CT may be caused if the longitudinal direction thereof is inclined similarly to the bit line contact 1B. So, the ground contact 1G in FIG. 5 is formed to be elongated in the direction in which the word line WL extends, without being inclined.

It is preferable that the bit line contact 1B is electrically coupled to the bit line BL by planarly overlapping it, and it is preferable that the ground contact 1G is electrically coupled to the ground line GND by planarly overlapping it. Accordingly, the ground contact 1G is formed to be elongated in the horizontal direction in FIG. 5 (i.e., in a direction intersecting the direction in which the ground line GND extends), in order to surely and planarly overlap them with each other. With such a configuration, the horizontal dimension becomes longer, and hence a mode can be made, in which the ground contact 1G more surely overlaps the ground line GND extending vertically, even if the position of the ground contact 1G is more or less shifted. The bit line contact 1B is elongated in the inclined direction, and with such an elongated shape, a mode can be made, in which the bit line contact 1B more surely overlaps the bit line BL extending vertically (in comparison with the case where, for example, at least the bit line contact 1B extends in parallel with the bit line BL, similarly to the storage node contact SC), even if the position of the bit line contact 1B is more or less shifted.

In contrast to the bit line contact 1B and the ground contact 1G, it is preferable that the storage node contact SC does not planarly overlap the bit line BL, etc. The storage node contact SC is a portion that forms the cross couple, and hence there is the possibility that the function is impaired if it is electrically coupled to the bit line BL. Accordingly, a contact between the storage node contact SC and the bit line BL can be suppressed by arranging the storage node contact SC between a pair of the bit lines BL adjacent to each other. Further, a contact between the storage node contact SC and the bit line BL can be suppressed by forming the storage node contact SC to be elongated in the direction in which the bit line BL extends.

Thus, the first contact patterns include both the storage node contact SC that is a contact pattern elongated in the direction in which the bit line BL extends in plan view, and the ground contact 1G that is a contact pattern elongated in the direction in which the word line WL extends in plan view. That is, contact patterns elongated, if necessary, in a different direction such as the vertical direction, the horizontal direction, or an inclined direction in the view, coexist in the semiconductor device. With such a configuration, a short circuit between the contact patterns can be more surely suppressed in comparison with the case where all of the contact patterns are similarly inclined or extend in the same direction, irrespective of the requirements in terms of pattern. Further, the required function of an SRAM can be exerted by distinguishing, if necessary, the contact pattern CT to be electrically coupled to the bit line BL, etc., (to be planarly overlapped) from the contact pattern CT not to be electrically coupled thereto (not to be planarly overlapped).

As described above, it is particularly preferable that the bit line contact 1B (as a third contact pattern), for coupling one of the source/drain region of the access transistor (drain region D in FIG. 2) and the bit line contact 1B, is formed to be elongated in the direction inclined with the directions in which the bit line BL and the word line WL extend. This is because: the distance between the aforementioned bit line contact 1B and the storage node contact SC adjacent thereto (over the gate electrode over a region that is not the active region) is particularly small; and hence a short circuit is likely to occur between them. A short circuit can be suppressed from occurring by inclining the bit line contact 1B as described above to make the distance between the bit line contact 1B and the storage node contact SC be large.

The case where one embodiment is applied to an SRAM, in particular, to an Advanced SRAM has been described above, but without being limited thereto, the one embodiment can also be applied, for example, to a DRAM.

The invention made by the present inventors has been specifically described above based on preferred embodiments; however, it is needless to say that the invention should not be limited to the preferred embodiments and various modifications may be made to the invention within a range not departing from the gist of the invention.

What is claimed is:

1. A semiconductor device comprising:
a semiconductor substrate having a main surface;
a bit line extending over the main surface;
a word line extending over the main surface so as to intersect the bit line in plan view;
a plurality of first contact patterns including at least one of a contact pattern elongated in a direction in which the bit line extends, and a contact pattern elongated in a direction in which the word line extends in plan view; and
a plurality of second contact patterns each elongated in directions inclined with respect to the respective directions in which the bit line and the word line extend in plan view,
wherein the first contact patterns and the second contact patterns are formed in the same layer over the main surface.

2. The semiconductor device according to claim 1,
wherein the first contact patterns include both a contact pattern elongated in the direction in which the bit line extends in plan view, and a contact pattern elongated in the direction in which the word line extends in plan view.

3. The semiconductor device according to claim 1 further comprising:
a static-type memory cell access transistor,
wherein the access transistor includes a pair of source/drain regions, and
wherein each of the second contact patterns couples one of the pair of the source/drain regions of the access transistor and the bit line.

4. The semiconductor device according to claim 1 further comprising:
a plurality of first coupling layers and a plurality of second coupling layers, each of which is coupled to the main surface, and
wherein each of the first contact patterns is formed to be in contact with an upper surface of each of the first coupling layers, and each of the second contact patterns is formed to be in contact with an upper surface of each of the second coupling layers.
